(19) United States
(12) Patent Application Publication
(10) Pub. No.: US 2014/0002093 A1
(43) Pub. Date: Jan. 2, 2014

(54) RELAY CONTACT MONITORING AND CONTROL

(71) Applicants: Randall B. Elliott, Tigard, OR (US); David E. Burgess, Beaverton, OR (US)

(72) Inventors: Randall B. Elliott, Tigard, OR (US); David E. Burgess, Beaverton, OR (US)

(73) Assignee: LEVITON MANUFACTURING CO., INC., Melville, NY (US)

(21) Appl. No.: 13/534,010

(22) Filed: Jun. 27, 2012

(51) Int. Cl. G01R 31/327

(52) U.S. Cl. 324/423; 324/418

(57) ABSTRACT

A method for determining an actuation delay time for an electromechanical relay includes capturing a current waveform of an energized coil, determining a time at which the actuation component begins to move by analyzing the captured current waveform, and calculating the actuation delay time for the relay based on the time at which the actuation component begins to move. A method for determining a state of a latching relay includes energizing the coil of the latching relay, capturing a current waveform of the energized coil, and determining the state of the relay by analyzing the captured current waveform.

### BACKGROUND

Relays are widely used to control the flow of power from AC power sources to various types of electrical loads. A typical electromechanical relay includes one or more sets of contacts that open or close to establish and interrupt the flow of power, and an electromagnetic coil that is energized or de-energized to move an actuation component that opens or closes the contacts. Relay contacts have a limited lifespan which can be greatly increased if the opening and/or closing of the contacts can be synchronized with zero crossing points in the AC voltage and/or current waveforms. Synchronizing the closing of relay contacts with a zero crossing, however, can be difficult because there is an actuation delay between the time at which the coil is energized or de-energized and the time at which the contacts actually close or open. If the delay time is known, it can be compensated for by energizing the coil in advance of a zero crossing by the known delay time so that the contacts close at actual zero crossing. This delay time, however, can be unpredictable and tends to vary based on closing versus opening, manufacturing, environmental and aging factors.

FIG. 1 illustrates a prior art technique for determining an actuation delay time for a relay. When the relay coil is energized by the application of a DC voltage, the instantaneous coil current is monitored with a slope detector circuit. According to this technique, which is disclosed in U.S. Pat. No. 6,233,132, the transition from negative to positive slope creates a current “valley” shown at 102 which indicates the point at which the contacts close. Thus, according to this technique, the actuation delay time is determined as the time between enabling the coil and detecting the current valley.

### BRIEF DESCRIPTION OF THE DRAWINGS

FIG. 1 illustrates a prior art method for determining an actuation delay time for an electromechanical relay.

FIG. 2 illustrates a magnetic latching relay having an armature and contacts in the open position.

FIG. 3 illustrates a magnetic latching relay having an armature and contacts in which the contacts are touching but the armature is transitioning between the open and closed positions.

FIG. 4 illustrates a magnetic latching relay having an armature and contacts in the fully closed position.

FIG. 5 illustrates an embodiment of a method for determining an actuation delay time for a magnetic latching relay according to some inventive principles of this patent disclosure.

FIG. 6 illustrates the current waveform that is captured when a coil is energized with a voltage pulse and the relay is already latched in the state associated with that coil according to some inventive principles of this patent disclosure.

FIG. 7 illustrates the current waveform that is captured when a coil is energized and the relay is not already latched in the state associated with that coil according to some inventive principles of this patent disclosure.

FIG. 8 illustrates the current waveform that is captured when a coil is energized and the relay is stuck in the present latched state according to some inventive principles of this patent disclosure.

FIG. 9 illustrates a method in which the initial slope of a coil current waveform is determined shortly after the coil is energized according to some inventive principles of this patent disclosure.

FIG. 10 illustrates a method in which the instantaneous value of the captured current waveform measured according to some inventive principles of this patent disclosure.

FIG. 11 is a flow diagram illustrating an embodiment of a method for determining the state of a latching relay profile according to some inventive principles of this patent disclosure.

FIG. 12 illustrates an embodiment of a relay control system according to some inventive principles of this patent disclosure.

FIG. 13 is a flow diagram illustrating an embodiment of another method for determining the state of a latching relay according to some inventive principles of this patent disclosure. This

FIG. 14 is a flow diagram illustrating an embodiment of another method for determining the state of a latching relay according to some inventive principles of this patent disclosure. This

### DETAILED DESCRIPTION

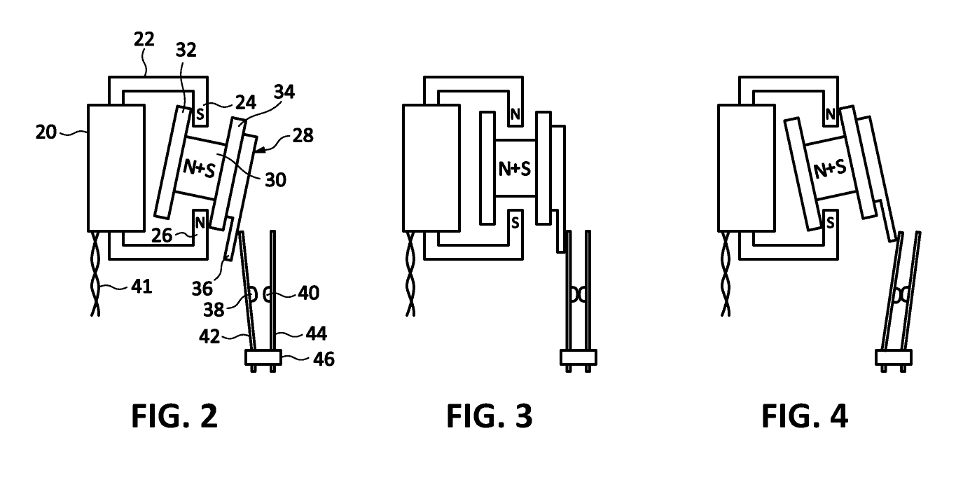

FIG. 2 illustrates a magnetic latching relay having an armature and contacts in the open position. The relay includes an electromagnet coil 20 having a C-shaped core 22 with a first pole piece 24 and a second pole piece 26. An armature 28 pivots around a pivot point indicated by the “+” sign. The armature 28 includes a permanent magnet 30 having north (“N”) pole piece 32 and a south (“S”) pole piece 34. The armature 28 also includes an actuator lever 36. Electrical contacts 38 and 40 are mounted on resilient levers 42 and 44, respectively, which are secured on a stationary base 46.

In the position shown in FIG. 2, the coil 20 is de-energized, but the top and bottom pole-pieces 24 and 26 have S and N-type magnetism, respectively, due to the permanent magnetic field being conducted through the C-shaped core. Thus, the top of the N pole-piece on the armature is attracted to the S pole-piece 24 on the top of the core 22, and the bottom of the S pole-piece 34 is attracted to the N pole-piece 26 on the bottom of the core 22. This latches the armature in the position shown in FIG. 2 in which the resilient lever 42 is biased against the actuator lever 36, and the contacts 38 and 40 are open.

FIG. 3 illustrates the relay of FIG. 2 as the armature 28 rotates in the counterclockwise direction in response to energization of the coil 20. The coil 20 is energized by applying a suitable voltage pulse to electrical leads 40 with a polarity that magnetizes the core 22 in the opposite direction such that the top and bottom pole-pieces 24 and 26 become N and S-type magnetic poles, respectively. This causes the top of the N pole-piece 32 on the armature to be repelled by what has become the N pole-piece 24 on the top of the core 22, while the top of the S pole-piece 34 is attracted to the N pole-piece 24. Likewise, the bottom of the S pole-piece 26 of the armature is repelled by what has become the S pole-piece 26 on the bottom of the core 22, while the bottom of the N pole-piece 24 is attracted to the S pole-piece 26.

FIG. 3 illustrates the armature 28 at a moment in which it has rotated to a position in which the actuator lever 36 has pushed against the resilient lever 42 until the contacts 38 are 40 are barely touching, and beginning to make electrical contact.

FIG. 4 illustrates the relay of FIG. 2 after the armature 28 has rotated to the fully counterclockwise position. The coil 20 has been de-energized, but now the reversed magnetic polarity of the top and bottom pole-pieces 24 and 26 is maintained from the permanent magnetic field being conducted through the C-shaped core. Thus, the top of the S pole-piece 32 on the armature is attracted to the N pole-piece 24 on the top of the core 22, and the bottom of the N pole-piece 34 is attracted to the S pole-piece 26 on the bottom of the core 22. This latches the armature in the position shown in FIG. 4 in which the actuator lever 36 pushes the resilient lever 42 so the spring force of the resilient lever 42 cannot hold the contacts 38 and 40 open, and the contacts remain closed.

The attraction of the pole pieces 32 and 34 of the permanent magnet 30 on the armature 28 to the permanent magnetic field being conducted through the respective pole pieces of the magnetic core 22 retains the armature in the position shown in FIG. 4, and thus the contacts 38 and 40 remain closed until a voltage pulse of the opposite polarity is applied to the coil 20, thereby reversing the process and returning the armature to the position shown in FIG. 2, with the contacts first opening in the position shown in FIG. 3.

In the example of FIGS. 2-4, the relay is a latching type relay in which the armature 26 and contacts 36 and 44 remain in the closed position shown in FIG. 4 even after the coil 20 is de-energized. Although non-latching type relays employ different mechanisms to open and close their contacts, their contacts are typically mounted on some type of resilient component that flexes after the contacts close to provide spring force to keep the contacts closed. Thus, non-latching relays typically exhibit a sequence in which the electrical contacts close before their associated armature or other mechanism reaches a mechanical stop, just as with a latching relay.

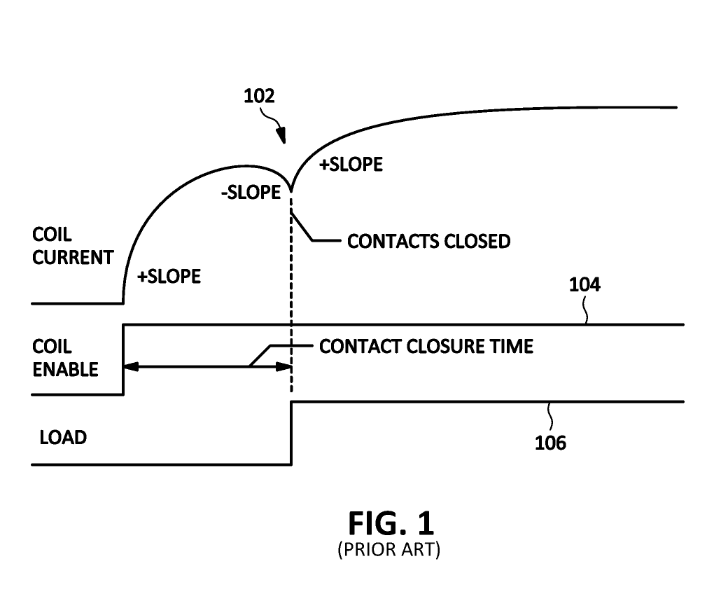

The sequence illustrated in FIGS. 2 through 4 illustrate a problem with the prior art method of determining the actuation delay discussed in the Background. Specifically, the prior art method shown in FIG. 1 assumes the contacts close at the same instant as the valley 102 in the waveform of the coil current 100. This, however, is an incorrect assumption. The valley 102 is actually caused by the armature hitting a mechanical stop—so the contacts actually close prior to the valley. Thus, if a relay is closed using an actuation delay that is based on using the valley as the time at which the contacts close, the timing will be incorrect, and the contacts will close prior to the zero-crossing.

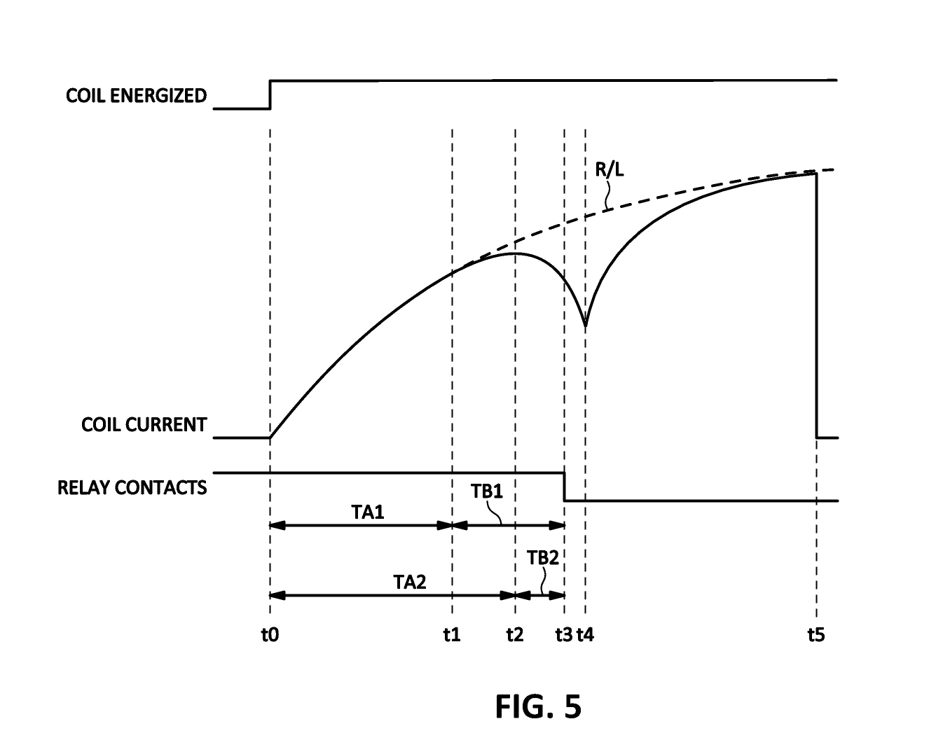

FIG. 5 illustrates some techniques for determining and using a relay actuation delay according to some of the inventive principles of this patent disclosure. In the timing diagram of FIG. 5, the top trace indicates whether the coil is energized or de-energized with a DC drive voltage, the middle trace represents the coil current, and the bottom trace shows the state of the relay contacts wherein a high level indicates that contacts are open and a low level indicates the contacts are closed. The timing diagram of FIG. 5 is illustrated in the context of a latching relay such as that illustrated in FIGS. 2-4, but the inventive principles are applicable to other types of relays as well.

Prior to time t0, the the relay is de-energized, no coil current is flowing, and the armature is held in the position shown in FIG. 2 because the N pole-piece on the armature is attracted to the conducted S magnetism of the top pole-piece 24 of the core, and the bottom of the S pole-piece on the armature is attracted to the conducted N magnetism of the bottom pole-piece 26 of the core. With the armature in this position, the resilient lever 42 is biased against the actuator lever 36, and the contacts 38 and 40 are open.

At time t0, the coil is energized by applying a DC voltage pulse to the coil leads 41. The applied voltage pulse has the opposite polarity of the previous voltage pulse.

Between time t0 and t1, the coil current increases in the form of an inverse logarithmic curve for a resistive-inductive (R/L) circuit shown by the broken line in FIG. 5. The resistance R is determined by the series resistance of the coil winding. The inductance L is determined by the physical configuration of the coil 20 including the number of winding turns, as well as the attributes of the magnetic circuit formed by the core 22, and the armature 28. As the coil current increases, the coil winding creates an electromagnetic field in the core that opposes the magnetic polarity of the permanent magnetic field in the armature so that the conducted magnetism is eventually completely cancelled and reversed, and the core is gradually magnetized in the opposite polarity.

At time t1, the armature begins to rotate because the magnetic polarity of the core has reversed to the point that the top of the N pole-piece 32 on the armature is repelled by what has become the N pole-piece 24, while the top of the S pole-piece 34 is attracted to the N pole-piece 24 Likewise, the bottom of the S pole-piece 26 of the armature is repelled by what has become the S pole-piece 26, while the bottom of the N pole-piece 24 is attracted to the S pole-piece 26.

The rotation of the armature creates a back electromotive force (back EMF) in the coil 20 that causes the coil current to depart from the R/L curve as shown by the solid line diverging from the broken line in FIG. 5.

By time t2, the back EMF induced by the rotation of the armature has caused the coil current to begin decreasing. Thus, there is a local peak in the coil current at time t2 caused by rotation of the armature. This is the first local peak in the coil current after the coil is energized. The slope of the coil current at this first local peak changes from positive to negative. As the armature continues to rotate, the coil current continues to decrease accordingly.

At time t3, which occurs somewhere between t2 and t4, the armature reaches a point where the electrical contacts close as shown by the bottom trace. This moment is illustrated by FIG. 3 which shows that the contacts are touching, but the pole pieces on the armature have still not hit the pole pieces of the electromagnet core 22.

Between time t3 and time t4, the armature continues to rotate and the actuator lever 36 pushes the resilient lever 42 so the resilient levers 42 and 44 hold the contacts 38 and 40 closed with increasing spring force.

At time t4, the armature stops rotating abruptly as the pole pieces of the armature 26 strike the pole pieces of the core 22, and the armature comes to rest in the position shown in FIG. 4. When the armature stops rotating, it no longer generates a back EMF in the coil 20, so the coil current begins increasing rapidly again and converges with the R/L curve as shown in FIG. 5. Thus, there is a second inflection point in the current at time t4. The coil current eventually reaches a maximum value determined by the winding resistance of the coil.

At time t5, the voltage pulse is removed from the coil, and the armature remains in the position shown in FIG. 4 due to the attraction of the armature pole pieces to the conducted magnetism through the core pole pieces.

The principles illustrated in the context of FIG. 5 enable the implementation of numerous methods for determining and using a relay actuation delay. Whereas the prior art determines an actuation delay by looking for the second inflection point at t4 and assuming that the second inflection point is when the contacts close, the inventive principles enable more accurate determinations of the actual time at which the relay contacts close by determining the time at which the armature or other component that actuates the contacts, such as a cam or plunger, begins to move. The actuation delay time may then be calculated as the time period between the time at which the coil is energized, and the time at which motion of the actuator is detected, with the optional inclusion of one or more additional time periods to adjust for the movement time of the actuator before the contacts close.

As a first example, motion of the actuator may be detected by looking for the point at which the coil current begins to deviate from the R/L curve, i.e., time t1 in the embodiment described above with respect to FIG. 5. The actuation delay time may then be calculated as the time period TA₁ between the time the coil is energized at time t0 and the time the armature begins to move at time t1. Optionally, the contact travel time TB₁ between the time the armature begins to move at time t1 and the time the contacts close at time t3 may be added to TA₁ to adjust the total actuation delay time for movement of the armature.

As a second example, motion of the actuator may be detected by looking for the point at which the coil current begins to decrease, i.e., the local peak or first inflection point shown as time t2 in the embodiment of FIG. 5. The actuation delay time may then be calculated as the time period TA₂ between the time the coil is energized at time t0 and the time the armature begins to move at time t2. Optionally, the contact travel time TB₂ between the current peak at time t2 and the time the contacts close at time t3 may be added to TA₂ to adjust the total actuation delay time for movement of the armature.

The contact travel times TB₁ and TB₂ may be determined in any suitable manner. For example, in some embodiments, it may be determined through measurement during the manufacturing process and programmed into nonvolatile memory in a microcontroller for the relay. In other embodiments, it may be determined dynamically by monitoring the voltage across the relay contacts, for example as part of a zero-crossing detection circuit, to determine the precise time at which the contacts close.

Some additional inventive principles of this patent disclosure relate to techniques for monitoring and/or compensating for contact wear. Referring to FIG. 5, as the contacts wear out, the time t3 at which the contacts first close occurs later and later, i.e., begins to drift toward time t4. The contacts may be considered to be worn out when the contact closure time t3 coincides with the time the armature strikes the core at time t4. The contact closure time t3 may be monitored, for example, by monitoring the voltage across the contacts. By monitoring the contact closure time t3, and determining the inflection point t4 at which the armature stops rotating, a system according to the inventive principles of this patent disclosure can determine that the contacts have worn out and take appropriate action. For example, the system may transmit a maintenance request to a building automation system. Alternatively, the system may disable the relay from closing the contacts if they have reached the point of wearing out.

Some additional inventive principles of this patent disclosure relate to techniques for determining the state of a latching relay by analyzing the waveform of the current flowing through a relay coil when the coil is energized.

Latching relays consume less energy than non-latching relays because they only require short pulses of current to switch states. Once the state of a latching relay is switched, it is maintained in the new state by a mechanical, magnetic or other latching device until the relay switches states again in response to another current pulse. The relay contacts maybe actuated by an armature, plunger, cam or other actuation component on which the latching device may operate.

Some latching relays include two different coils: one coil is energized with a voltage pulse to switch the relay to a first state, and the other, opposing coil is energized with a voltage pulse to switch the relay to a second state. Some other latching relays include only a single coil that is energized with a voltage pulse having a first polarity to switch the relay to the first state, and energized with a voltage pulse of the opposite polarity to switch the relay to the second state.

Determining the state of a latching relay may be useful to verify that the relay is initialized to a proper power-up state, to verify that an intended switching even occurred, to test for a stuck relay (e.g., due to welded contacts), etc.

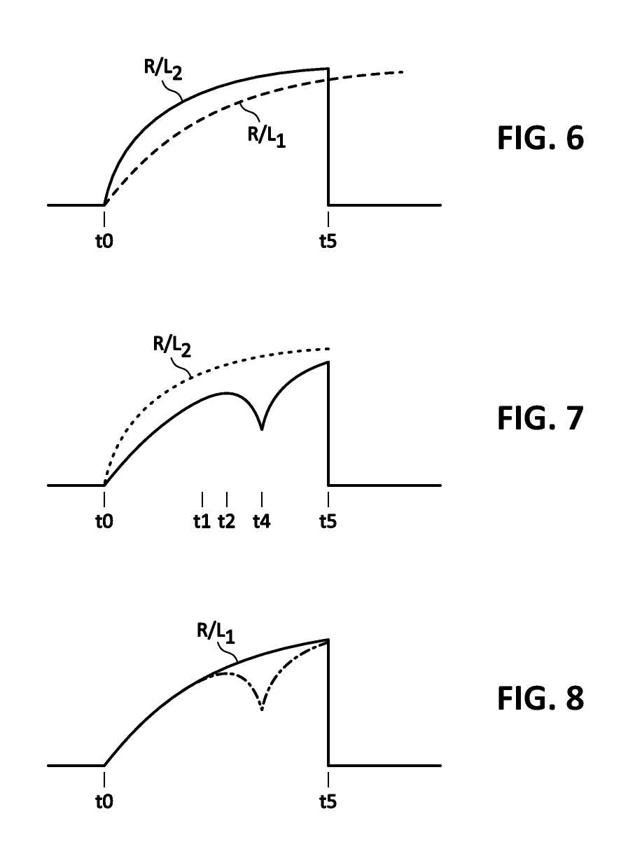

FIGS. 6-8 illustrate an embodiment of a method for determining the state of a latching relay according to some inventive principles of this patent disclosure. The method of FIGS. 6-8 is described in the context of a latching relay having a single coil that is energized with voltage pulses of different polarities to switch states, but the inventive principles may also be applied to latching relays having two different coils to switch logical states.

FIG. 6 illustrates the current waveform that is captured when a coil is energized with a voltage pulse of a specific polarity and the relay is already latched in the state associated with that polarity. The voltage pulse is applied at time t0, at which point the current begins increasing in the form of an inverse logarithmic curve for a resistive-inductive circuit having a time constant R/L₂. The resistance R is determined by the series resistance of the coil winding. The inductance L₂ is determined by the physical configuration of the coil winding including the number of turns, as well as the characteristics of the rest of the magnetic circuit including the polarity of the permanent magnet armature's latched position.

Because the relay is already latched in the state associated with the polarity of the voltage pulse, the core of the coil is already magnetized with the final magnetic polarity, so there is no change in the magnetic circuit. The inductance L2 appears smaller than L1 because the electromagnetic field is being aided by the armature's permanent magnet field instead of opposing it. The inductance L2 does not change, and the coil current continues to follow the inverse logarithmic curve for a resistive-inductive circuit having a time constant R/L₂ until the voltage pulse is removed at time t5. For comparison, the dashed line in FIG. 6 shows the curve for a resistive-inductive circuit having a time constant R/L₁ which would be followed by the initial current waveform if the relay was latched in the other state when the voltage pulse was applied.

Thus, the method can determine which logical state the relay is latched in because the captured current waveform matches the current profile expected from a latched relay.

FIG. 7 illustrates the current waveform that is captured when a coil is energized and the relay is not already latched in the state associated with that polarity of voltage pulse. The waveform illustrated in FIG. 7 is similar to that shown in FIG. 5.

Because the relay is initially latched in the opposite state at time t0, the coil current initially follows the curve for a resistive-inductive circuit having a time constant R/L₁ because the conducted magnetism of the core must be reversed. At time t1, the armature or other actuation component begins to move, so a back EMF is generated in the coil, thereby causing the current to begin deviating from the R/L₁ curve. At time t2, a first point of inflection is reached, and the coil current begins to decrease as the actuation component continues moving toward the opposite latched position. At time t4, the actuation component reaches the opposite latched position, i.e., hits a mechanical stop, thereby creating a second inflection point and causing the coil current to increase rapidly until it converges with the R/L₁ curve. For purposes of comparison, the dotted line in FIG. 7 shows the curve R/L₂ that the coil current would follow if the relay was already latched in the state associated with the polarity of the voltage pulse.

The method can therefore determine that the relay is switching to the opposite latched state by comparing the captured current waveform to the current profile expected when the relay switches to the opposite latched state. The determination may be made using any or all of the cues shown in FIG. 7. For example, because the initial current follows the curve for R/L₁ instead of R/L₂, this may indicate that the relay was initially in the opposite latched state. However, as explained in more detail below, this may also indicate that the relay is stuck in a latched position as well.

Alternatively, or in addition to the initial rate at which the current increases, the method may look for any of the other cues shown in FIG. 7 to determine that the relay is switching to the latched state. These cues include the deviation from the R/L₁ curve at time t1, the peak or first point of inflection at time t2 and/or the second point of inflection at time t4.

FIG. 8 illustrates the current waveform that is captured when a coil is energized and the relay is stuck in the opposite latched state, which may be caused for example by the relay contacts being welded in the opposite latched position. The voltage pulse is applied at time t0, at which point the current begins increasing at a rate that follows the R/L₁ curve, just as in the example of FIG. 7. However, because the relay in the embodiment of FIG. 8 is stuck in the opposite latched state, the actuation component does not move. Therefore, rather than following the profile that the current would normally follow as the relay switches to the opposite latched state (shown in FIG. 8 as a dotted-dashed line), the current simply continues following the curve for the R/L₁ time constant until the pulse is terminated at time t5.

Thus, the method determines that the relay is stuck in the opposite latched state by first detecting that the coil current follows the R/L₁ curve, then observing the lack of cues that would normally be seen when the relay switches logical states.

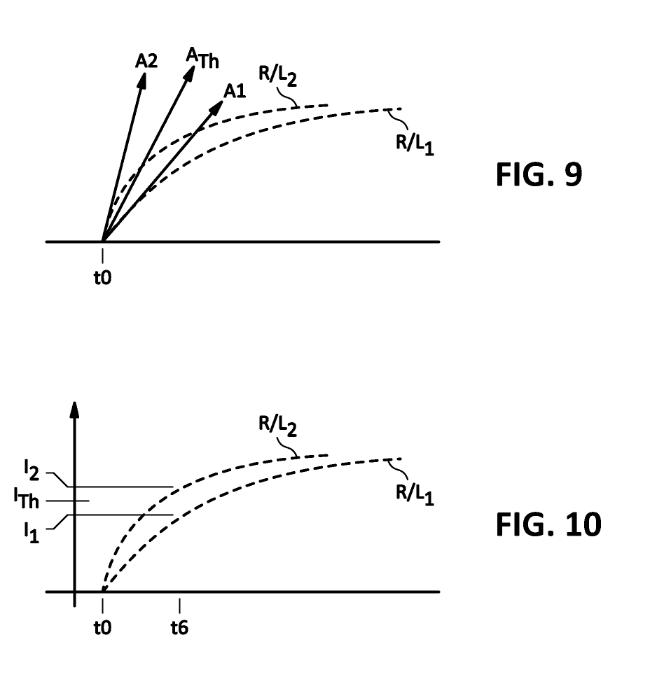

The inventive principles of this patent disclosure contemplate various techniques for analyzing a captured waveform and/or comparing a captured waveform to a profile. For example, FIG. 9 illustrates a method in which the initial slope of the coil current waveform is determined shortly after the coil is energized at time t0. A captured current waveform that follows the R/L₂ curve has an initial slope A2 as shown in FIG. 9, whereas a waveform that follows the R/L₁ curve has an initial slope A1. Therefore, a determination can be made as to which logical state the relay is latched in by establishing a threshold slope A_{Th} between initial slopes of the R/L₁ and R/L₂ curves, and then comparing the measured slope to the threshold slope to determine which of the two curves the captured waveform is initially following.

Another example technique is illustrated in FIG. 10 where the instantaneous value of the captured current waveform measured at some time t6 is compared to a threshold value I_{Th}. If the measured value is greater than I_{Th}, e.g., I₂, the coil current is assumed to be following the R/L₂ curve, but if the measured value is less than I_{Th}, e.g., I₁, the coil current is assumed to be following the R/L₁ curve.

Other examples of techniques for analyzing a captured waveform and/or comparing a captured waveform to a profile according to the inventive principles of this patent disclosure include differentiating the entire captured waveform and looking for points of zero slope to indicate points of inflection, and using curve fitting techniques to find a best fit of a captured waveform to one or more known profiles.

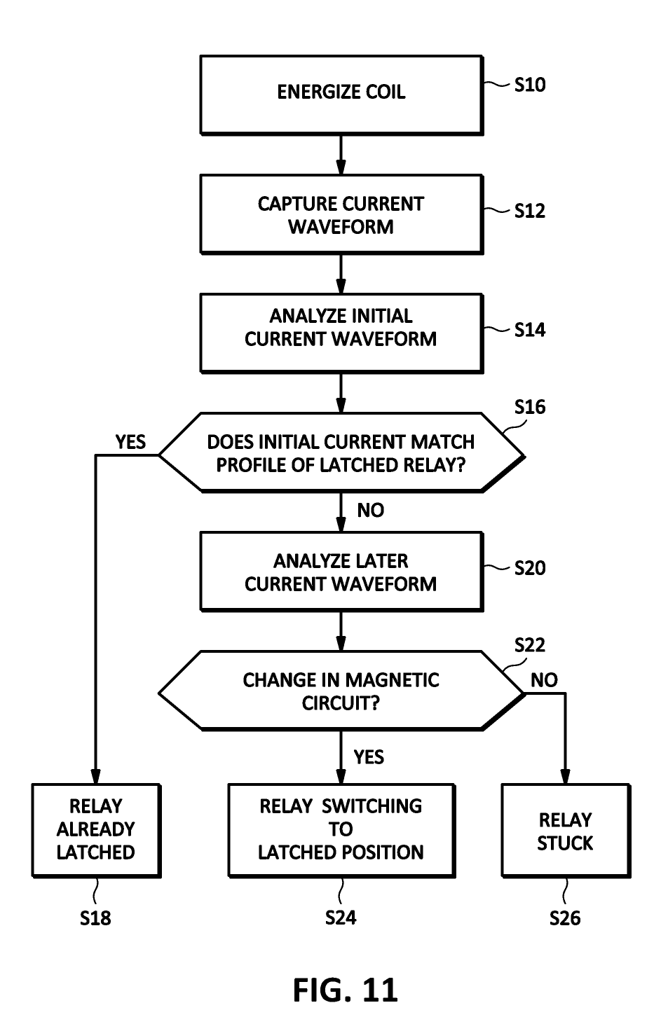

FIG. 11 is a flow diagram illustrating an embodiment of a method for determining the state of a latching relay according to some inventive principles of this patent disclosure. The method begins by energizing a relay coil at S10. The resulting current waveform is captured at S12 and analyzed at S14. At S16, the rate at which the coil current rises is evaluated. If the rate at which the current initially rises matches the profile of a relay that is latched already, i.e., the coil current rises relatively fast, the relay is determined to already be latched in the intended state at S18, and the method terminates.

If, however, the rate at which the current initially rises does not match the profile of a relay that is latched already, i.e., the coil current rises relatively slowly, the method proceeds to S20 where the captured waveform is further analyzed to look for signs of changes in the magnetic circuit that includes the actuation component. These changes may include deviations from the initial R/L curve, one or more inflection points in the current waveform, etc. At S22, any detected changes are evaluated. If one or more cues indicate that the magnetic circuit has changed enough to indicate with a high enough degree of certainty that the actuation component has moved, the relay is determined to have just switched to the latched state at S24, and the method terminates. However, if no or too few cues indicate that the magnetic circuit has changed, the relay is determined to be stuck at S26 and the method terminates.

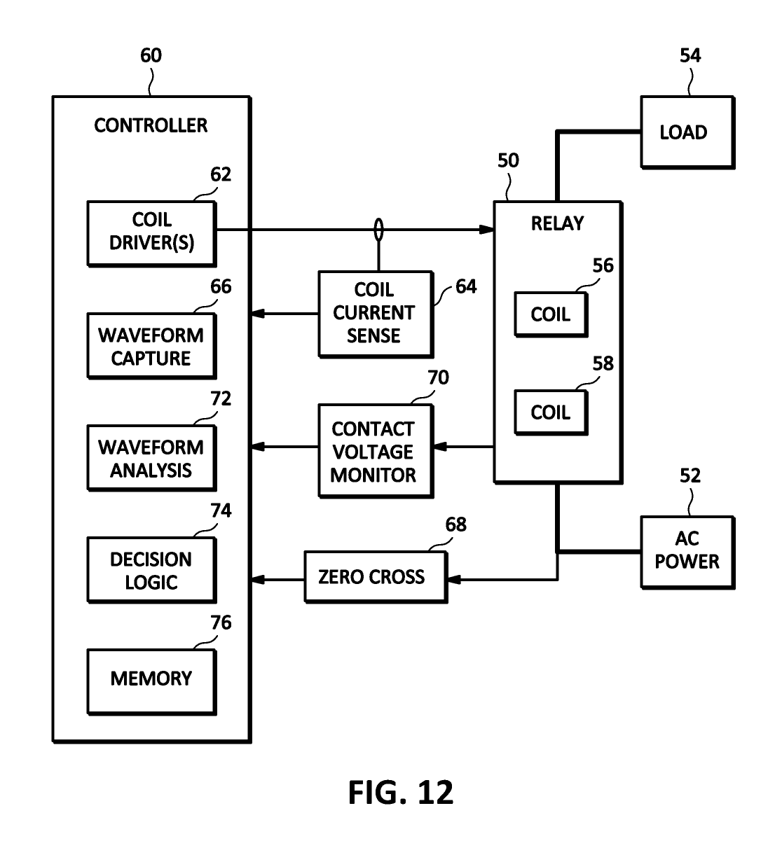

FIG. 12 illustrates an embodiment of a relay control system according to some inventive principles of this patent disclosure. The system of FIG. 12 may be used to implement any of the methods described above for determining an actuation delay time for a relay, determining the state of a latching relay, as well as various other uses according to the inventive principles of this patent disclosure.

The embodiment of FIG. 12 includes an electromechanical relay 50 having one or more sets of contacts for controlling the flow of power from an AC power source 52 to a load 54. In this example, the relay is assumed to be a latching relay having a first coil 56 for closing the contacts and a second coil 58 for opening the contacts, but other relay types may be used depending on which features are to be implemented.

A controller 60 includes a coil driver 62 to selectively energize the coils 56 and 58. One or more current sensors 64 sense the current flowing to the coils and enable a waveform capture feature 66 in the controller 60 to capture the waveform of the current flowing through an energized coil. The current sensors 64 may be implemented with one or more current transformers, current shunts, Hall Effect sensors, etc. The waveform capture feature 66 may be implemented for example with an A/D converter that is separate from, or integral with, a microcontroller which may be used to implement the controller 60.

A zero cross detection circuit 68 enables the controller to synchronize the opening and/or closing of the relay contacts with the AC waveform using, for example, an actuation delay time it may calculate using any of the methods described herein. An optional contact voltage monitor 70 may be included to enable the controller to detect the precise instant at which the relay contacts close. For example, a contact voltage monitor may enable the controller to determine the time t3 at which the contacts close in FIG. 5, thereby enabling the controller to calculate an actuator travel time TB. A contact voltage monitor may be implemented as a separate component 70 as shown in FIG. 12, or it may be inherent and/or integral in the zero cross detector 68. In a lesser featured system, the contact voltage monitor 70 may be eliminated completely to save cost.

The controller 60 may include various other features such as waveform analysis functionality 72 and decision logic 74 to enable the controller to analyze and compare waveforms and profiles, determine waveform attributes such as slopes, inflection points, curvatures, calculate actuation delay times, etc., and to make decisions as to the state of a latching relay. A memory 76 may be included to store waveforms, profiles, calculated delay times, results of decisions, etc. Any of the functionality of the controller 60 may be implemented with analog and/or digital hardware, software, firmware or any suitable combination thereof.

In one example embodiment, the controller 60 may be implemented as a single-board circuit board with a microcontroller having an on-board A/D converter for waveform capture. In such an embodiment, the controller 60, relay 50, current sensor(s) 64, contact voltage monitor 70 and zero crossing detection circuit 68 may be fabricated on a single circuit board, and contained within a common housing.

The embodiment of FIG. 12 may be used to implement a system wherein the controller is capable of capturing a current waveform of an energized relay coil, then analyzing the captured current waveform to determine a parameter of the relay. The parameter may be an actuation delay which is calculated using any of the methods described above, the state of a latching relay as determined using any of the methods described above, etc. Because the system may capture entire waveforms, rather than just looking for instantaneous features in the coil current, it may utilize post processing of the waveforms to provide a rich set of features that enable the implementation of more accurate techniques for determining actuation delays, latching relay state determination, etc.

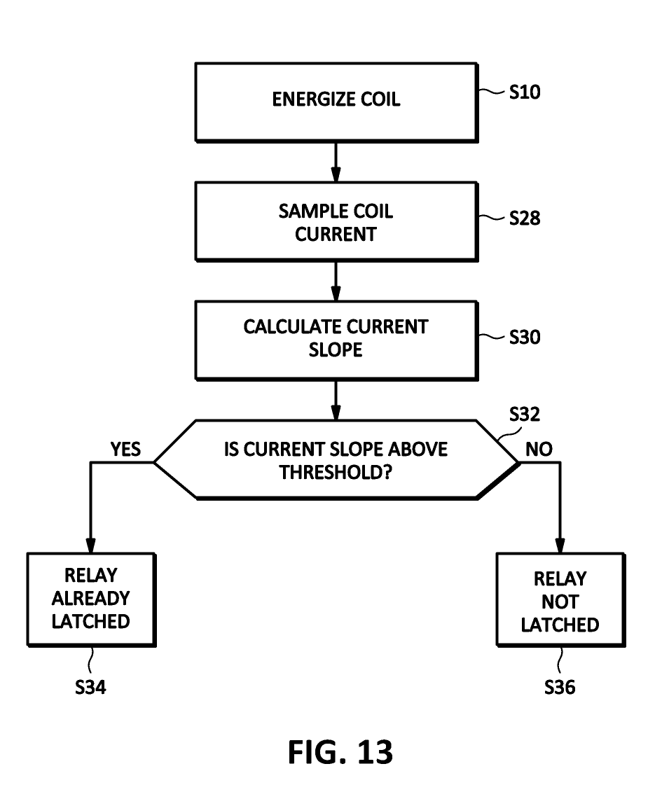

FIG. 13 is a flow diagram illustrating an embodiment of another method for determining the state of a latching relay according to some inventive principles of this patent disclosure. This flow utilizes the initial slope approach as described in FIG. 9. The method begins by energizing a relay coil with voltage pulse of a specified polarity at S10. A sample of the coil current is captured at S28. The rate at which the coil current rises is calculated at S30. The initial current rise is evaluated at S32. If the resulting rate is above the differentiating threshold A_{TH}, the relay is already latched in the position associated with the specified polarity, i.e., the relay current is determined to be following the R/L₂ curve, and the process terminates at S36. If the resulting rate of change is below the differentiating threshold A_{TH}, the relay is not latched in the position associated with the specified polarity, i.e., the relay current is determined to be following the R/L₁ curve, and the process terminates at S36.

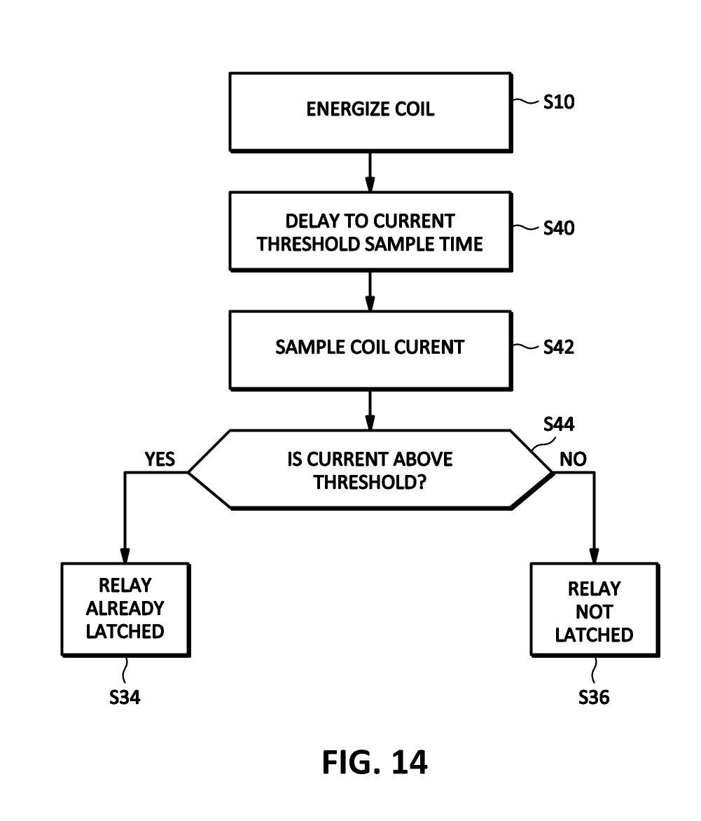

FIG. 14 is a flow diagram illustrating another embodiment of a method for determining the state of a latching relay according to some inventive principles of this patent disclosure. This flow utilizes the threshold current approach as described in FIG. 10. The method begins by energizing a relay coil with voltage pulse of a specified polarity at S10. A delay of an appropriate period is generated at S40 to cause the sample of the relay coil take in S42 to correspond to the point in the current curve that is represented by the predetermined current threshold. A sample of the coil current is captured at S42. The current value rise is evaluated at S44. If the resulting current is above the threshold current I_{Th}, the relay is already latched in the position associated with the specified polarity, i.e., the relay current is determined to be following the R/L₂ curve, and the process terminates at S34. If the resulting current is below the threshold current I_{Th}, the relay is not latched in the position associated with the specified polarity, i.e., the relay current is determined to be following the R/L₁ curve, and the process terminates at S36.

The inventive principles of this patent disclosure have been described above with reference to some specific example embodiments, but these embodiments can be modified in arrangement and detail without departing from the inventive concepts. Thus, any changes and modifications are considered to fall within the scope of the following claims.

1. A method for determining an actuation delay time for an electromechanical relay having a coil and an actuation component, the method comprising:
energizing the coil of the electromechanical relay;
capturing a current waveform of the energized coil in response to energizing the coil;
determining a time at which the actuation component begins to move by analyzing the captured current waveform; and
calculating the actuation delay time for the relay based on the time at which the actuation component begins to move.

2. The method of claim 1 wherein determining the time at which the armature begins to move comprises identifying a deviation in the current waveform caused by a change in a magnetic circuit including the actuation component.

3. The method of claim 2 wherein identifying the deviation in the current waveform comprises identifying a substantial deviation from an RL curve.

4. The method of claim 2 wherein identifying the deviation in the current waveform comprises identifying a first inflection point in the current waveform of the energized coil.

5. The method of claim 4 wherein the first inflection point comprises a peak in the current waveform of the energized coil.

6. The method of claim 1 wherein the actuation delay time includes a time period between energizing the coil and the time at which the actuation component begins to move.

7. The method of claim 6 wherein the actuation delay time further includes an actuator travel time.

8. The method of claim 7 wherein the actuator travel time is determined by monitoring a voltage across contacts of the relay.

9. A method for determining a state of a latching relay including a coil and an actuation component, the method comprising:
energizing the coil of the latching relay;
capturing a current waveform of the energized coil in response to energizing the coil; and
determining the state of the relay by analyzing the captured current waveform.

10. The method of claim 9 wherein analyzing the captured current waveform comprises determining how fast the coil current rises when the coil is energized.

11. The method of claim 10 wherein the relay is determined to have not switched states if the coil current rises faster than a threshold value.

12. The method of claim 11 wherein analyzing the captured current waveform further comprises looking for a deviation in the current waveform caused by a change in a magnetic circuit including the actuation component.

13. The method of claim 12 wherein the relay is determined to have switched states if:
the coil current rises faster than a threshold value; and
the deviation in the current waveform is found.

14. The method of claim 12 wherein the relay is determined to be stuck if:
the coil current rises slower than a threshold value; and
the deviation in the current waveform is not found.

15. The method of claim 9 wherein analyzing the captured current waveform comprises looking for a deviation in the current waveform caused by a change in a magnetic circuit including the actuation component.

16. The method of claim 15 wherein the relay is determined to have switched states if the deviation in the current waveform is found.

17. The method of claim 9 wherein analyzing the captured current waveform comprises comparing the captured waveform to one or more profiles.

18. A system comprising:
an electromechanical relay including a coil and an actuation component;
a controller coupled to the relay and constructed and arranged to energize the coil;
a current sensor arranged to sense current flowing through the coil when the coil is energized;
wherein the controller is coupled to the current sensor and constructed and arranged to capture a current waveform of the energized coil; and
wherein the controller is capable of analyzing the captured current waveform to determine a parameter of the relay.

19. The system of claim 18 wherein the parameter comprises an actuation delay.

20. The system of claim 18 wherein the parameter comprises a state of the relay.
